(19) United States
(12) Patent Application Publication
(10) Pub. No.: US 2019/0051648 A1
(43) Pub. Date: Feb. 14, 2019

(54) DIODE AND SEMICONDUCTOR DEVICE

(71) Applicant: TOYOTA JIDOSHA KABUSHIKI KAISHA, Toyota-shi, Aichi-ken (JP)

(72) Inventors: Noriyuki KAKIMOTO, Kariya-city (JP); Masaru SENOO, Okazaki-shi (JP)

(73) Assignee: TOYOTA JIDOSHA KABUSHIKI KAISHA, Toyota-shi, Aichi-ken (JP)

(21) Appl. No.: 16/066,450

(22) PCT Filed: Dec. 19, 2016
(86) PCT No.: PCT/JP2016/087721

§ 371 Date: Jun. 27, 2018

(30) Foreign Application Priority Data
Feb. 3, 2016 (JP) 2016-019253

(51) Int. Cl. H01L 27/06; H01L 29/423; H01L 29/739; H02M 7/5395; H01L 29/78; H01L 29/861

(52) U.S. Cl. CPC H01L 27/0629; H01L 29/4236; H01L 29/7397; H01L 29/861; H01L 29/7804; H01L 29/7813; H01L 29/7815; H02M 7/5395

(57) ABSTRACT

A diode includes a first-conductivity-type barrier region disposed between a drift region and a second impurity region and having an impurity concentration higher than that of the drift region and a second-conductivity-type field extension prevention region disposed between the barrier region and the drift region. The diode also includes a trench gate disposed to extend from a second main surface of a semiconductor substrate through the second impurity region and the barrier region and reach the field extension prevention region. The trench gate has a gate electrode for applying a gate voltage. A gate electrode is applied with a parasitic gate voltage, as the gate voltage. The parasitic gate voltage has an absolute value of a potential difference with a second electrode being equal to or greater than a threshold voltage of a parasitic transistor formed of the second impurity region, the barrier region, and the field extension prevention region.

### CROSS REFERENCE TO RELATED APPLICATION

This application is based on Japanese Patent Application No. 2016-19253 filed on Feb. 3, 2016, the disclosure of which is incorporated herein by reference.

### TECHNICAL FIELD

The present disclosure relates to a diode having a trench structure and a semiconductor device.

### BACKGROUND ART

Patent Literature 1 discloses a diode including a trench electrode in addition to an anode electrode and a cathode electrode. The disclosed diode includes an n-conductivity-type barrier region as an impurity region between a p-conductivity-type anode region and an n-conductivity-type drift region. The diode also includes a pillar region electrically connected to the anode electrode formed in contact with the anode region to extend through the anode region and reach the barrier region.

In the diode described in Patent Literature 1, the barrier region or the pillar region included therein inhibits injection of holes from the anode region into the drift region to provide an improved recovery characteristic and a higher-speed operation.

### PRIOR ART LITERATURE

### Patent Literature

Patent Literature 1: JP 2013-48230 A

### SUMMARY OF INVENTION

However, as a trade-off for the improved recovery characteristic, a forward voltage VF tends to increase compared with that in a conventional diode, which may increase a loss during the operation of the diode.

An object of the present disclosure is to provide a diode and a semiconductor device which simultaneously allow an improvement in recovery characteristic and a reduction in forward voltage.

In accordance with an aspect of the present disclosure, a diode includes a first electrode disposed on a first main surface of a semiconductor substrate, a first-conductivity-type first impurity region disposed in a surface layer of the semiconductor substrate adjacent to the first main surface and stacked on the first electrode, a first-conductivity-type drift region stacked on the first impurity region and having an impurity concentration lower than that of the first impurity region, a second-conductivity-type second impurity region stacked on the drift region, and a second electrode disposed on the second impurity region and on a second main surface of the semiconductor substrate which is opposite to the first main surface. The diode further includes a first-conductivity-type barrier region disposed between the drift region and the second impurity region and having an impurity concentration higher than that of the drift region, a second-conductivity-type field extension prevention region disposed between the barrier region and the drift region, and a trench gate disposed to extend from the second main surface through the second impurity region and the barrier region and reach the field extension prevention region. The trench gate has a gate electrode for applying a gate voltage. The gate electrode is applied with a parasitic gate voltage, as the gate voltage, and the parasitic gate voltage has an absolute value of a potential difference with the second electrode being equal to or greater than a threshold voltage of a parasitic transistor formed of the second impurity region, the barrier region, and the field extension prevention region.

In the diode described above, the parasitic gate voltage is the threshold voltage or more of the parasitic transistor formed of the second impurity region, the barrier region, and the field extension prevention region. This reduces the height of a potential barrier formed in the barrier layer. That is, in the barrier layer which forms the parasitic transistor when the parasitic gate voltage is applied to the gate electrode, a channel is formed. As a result, it is possible to increase the amount of charge injected from the second impurity region into the drift region and reduce a forward voltage VF. That is, the application of the parasitic gate voltage as the gate voltage offers an advantage against a loss. Accordingly, using the presence or absence of the application of the parasitic gate voltage, it is possible to simultaneously improve a recovery characteristic and reduce the forward voltage.

In accordance with another aspect of the present disclosure, a semiconductor device includes a reverse conducting switching element in which a diode and a switching element are formed in parallel in the same semiconductor substrate, a drive unit which applies a gate voltage to the reverse conducting switching element, and a mode determination unit which determines whether the reverse conducting switching element is driven in a forward conduction mode in which a current flows mainly in the switching element or in a reverse conduction mode in which a current flows mainly in the diode. The diode includes a first electrode disposed on a first main surface of a semiconductor substrate, a first-conductivity-type first impurity region disposed in a surface layer of the semiconductor substrate adjacent to the first main surface and stacked on the first electrode, a first-conductivity-type first drift region stacked on the first impurity region and having an impurity concentration lower than that of the first impurity region, a second-conductivity-type second impurity region stacked on the first drift region, a second electrode disposed on the second impurity region and on a second main surface of the semiconductor substrate which is opposite to the first main surface, a first-conductivity-type first barrier region disposed between the first drift region and the second impurity region and having an impurity concentration higher than that of the first drift region, and a second-conductivity-type first field extension prevention region disposed between the first barrier region and the first drift region. The switching element includes a second drift region disposed continuous to the first drift region, a body region disposed continuous to the second impurity region, a first-conductivity-type third impurity region disposed in a surface layer of the semiconductor substrate adjacent to the second main surface to be surrounded by the body region, and a second barrier region disposed continuously to the first barrier region. The diode and the switching element include a trench gate disposed to extend from the second main surface through the second impurity region and the first barrier region and reach the first drift region. The trench gate has a trench electrode for applying the gate voltage. In the reverse conduction mode, the drive unit applies a parasitic gate voltage as the gate voltage. The parasitic gate voltage has an absolute value of a potential difference with the second electrode being equal to or greater than a threshold voltage of a parasitic transistor formed of the second impurity region, the barrier region, and the field extension prevention region.

In the semiconductor device described above, in the forward conduction mode in which the current flows mainly in the switching element, it is possible to implement an operation which prioritizes an improved recovery characteristic over an increased loss due to the increased forward voltage VF. On the other hand, in the reverse conduction mode in which the current flows mainly in the diode, it is possible to suppress an increase in the forward voltage VF. That is, the application of the parasitic gate voltage as the gate voltage offers an advantage against a loss. Accordingly, using the presence or absence of the application of the parasitic gate voltage, it is possible to simultaneously improve the recovery characteristic and reduce the forward voltage.

### BRIEF DESCRIPTION OF DRAWINGS

The above and other objects, features and advantages of the present disclosure will become more apparent from the following detailed description made with reference to the accompanying drawings, in which:

FIG. 1 is a circuit diagram showing a schematic configuration of a semiconductor device according to a first embodiment;

FIG. 2 is a cross-sectional view showing a detailed structure of a reverse conducting switching element;

FIG. 3 is a timing chart showing the operation of a drive unit;

FIG. 4 is a circuit diagram showing a schematic configuration of a semiconductor device according to a first modification;

FIG. 5 is a timing chart showing the operation of a drive unit;

FIG. 6 is a timing chart showing the operation of a drive unit according to a second modification;

FIG. 7 is a circuit diagram showing a structure of a reverse conducting switching element according to a third modification;

FIG. 8 is a view showing a Forward Voltage VF-Recovery Loss Err characteristic;

FIG. 9 is a circuit diagram showing a structure of reverse conducting switching elements according to a fourth modification and a peripheral circuit thereof;

FIG. 10 is a circuit diagram showing a schematic configuration of a semiconductor device according to a second embodiment;

FIG. 11 is a timing chart showing the operation of a drive unit;

FIG. 12 is a flow chart showing the operation of the semiconductor device;

FIG. 13 is a view showing the behavior of a reactor current flowing in a load connected to the output terminal of a boosting converter;

FIG. 14 is a flow chart showing the operation of a semiconductor device according to a fifth modification;

FIG. 15 is a flow chart showing the operation of a semiconductor device according to a sixth modification; and

FIG. 16 is a cross-sectional view showing a detailed structure of reverse conducting switching elements according to a third embodiment.

### DESCRIPTION OF EMBODIMENTS

The following will describe the embodiments of the present disclosure on the basis of the drawings. In the following description of the drawings, like or equivalent component parts are given like reference characters or numerals.

### First Embodiment

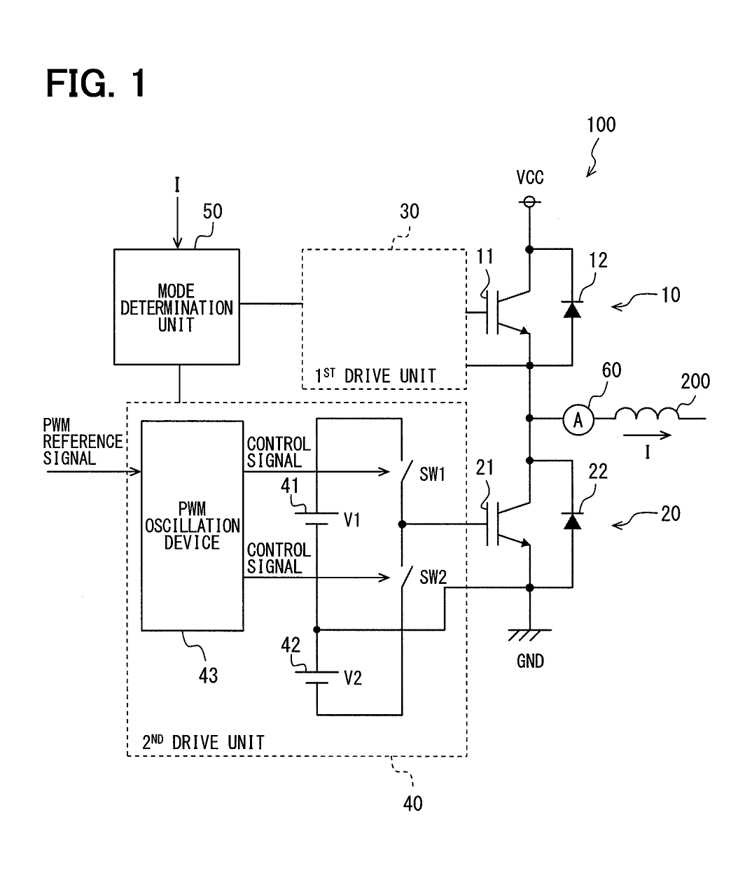

Referring first to FIG. 1, a description will be given of a schematic configuration of a diode according to the present embodiment and a semiconductor device including the diode.

In the present embodiment, a description will be given of a form in which the diode and the semiconductor device including the diode are applied to an inverter.

As shown in FIG. 1, an inverter 100 includes two reverse conducting insulated-gate bipolar transistors 10 and 20, drive units 30 and 40 for applying gate voltages to the respective gate electrodes of the individual reverse conducting insulated-gate bipolar transistors 10 and 20, and a mode determination unit 50 which determines the driven state of each of the reverse conducting insulated-gate bipolar transistors 10 and 20.

As shown in FIG. 1, the inverter 100 includes the two reverse conducting insulated-gate bipolar transistors 10 and 20 which are connected in series between a power source voltage VCC and a ground GND. To the connection point between the two reverse conducting insulated-gate bipolar transistors 10 and 20, a load 200 is connected. In the following description, the one of the two reverse conducting insulated-gate bipolar transistors 10 and 20 which is closer to the power source voltage VCC relative to the load 200 is referred to as the first element 10, while the other of the two reverse conducting insulated-gate bipolar transistors 10 and 20 which is closer to the ground GND relative to the load 200 is referred to as the second element 20. That is, the first element 10 forms an upper arm in the inverter 100, while the second element 20 forms a lower arm in the inverter 100. The first element 10 and the second element 20 correspond to reverse conducting switching elements.

The first element 10 as the reverse conducting insulated-gate bipolar transistor has an IGBT part 11 corresponding to a switching element and a diode part 12. The diode part 12 is a so-called flywheel diode and connected in parallel to the IGBT part 11 such that a forward direction extends from an emitter toward a collector in the IGBT part 11.

The second element 20 is equivalent to the first element 10 and has an IGBT part 21 and a diode part 22. The diode part 22 is connected in parallel to the IGBT part 21 such that a forward direction extends from an emitter toward a collector in the IGBT part 21.

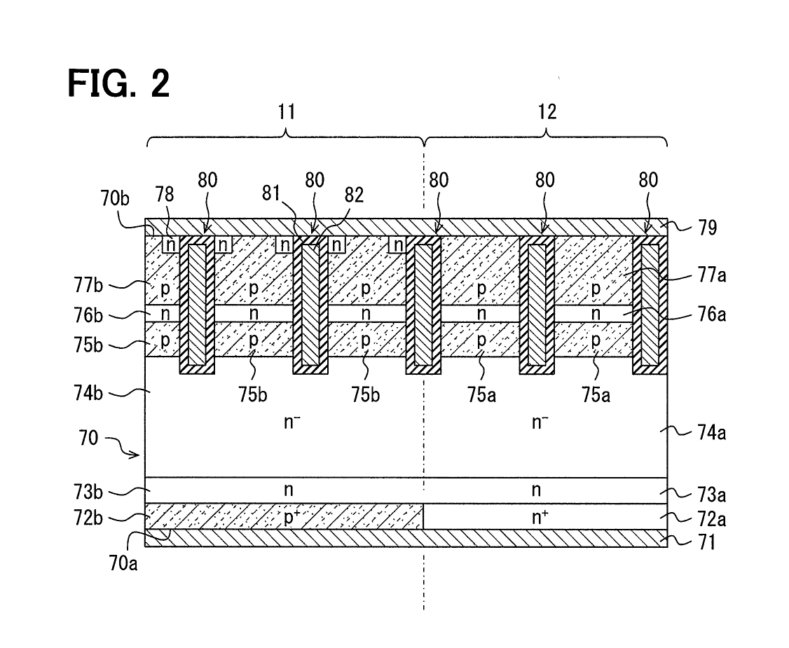

A detailed element structure of each of the first element 10 and the second element 20 will be described later in detail with reference to FIG. 2.

A drive unit includes the first drive unit 30 which controls the application of the gate voltage to the first element 10 and the second drive unit 40 which controls the application of the gate voltage to the second element 20. The first drive unit 30 and the second drive unit 40 are equivalent to each other. In FIG. 1, the illustration of a detailed configuration of the first drive unit 30 is omitted. The following will describe a detailed configuration of the second drive unit 40 included in the drive unit, but the first drive unit 30 also has the same configuration.

The second drive unit 40 has a voltage source 41 having an electromotive force V1, a voltage source 42 having an electromotive force V2, two switches SW1 and SW1, and a PWM oscillation device 43.

As shown in FIG. 1, the voltage source 41 and the voltage source 42 are connected in series, and the positive electrode of the voltage source 41 and the negative electrode of the voltage source 42 are connected to each other via the switches SW1 and SW2 connected in series to each other. The connection point between the voltage sources 41 and 42 connected in series to each other is connected to the emitter of the IGBT part 21, i.e., the anode of the diode part 22 and is at the ground potential GND in the second drive unit 40.

The gate electrode of the IGBT part 21 is connected to the connection point between the switches SW1 and SW2 connected in series to each other. Accordingly, in the state where, e.g., the switch SW1 is On and the switch SW2 is Off, the gate electrode of the IGBT part 21 is at a potential higher than a potential at the emitter by V1. On the other hand, in the state where, e.g., the switch SW1 is Off and the switch SW2 is On, the gate electrode of the IGBT part 21 is at a potential lower than the potential at the emitter by V2. That is, when the emitter potential in the IGBT part 21 is used as a reference, a voltage −V2 is applied to the gate electrode.

The PWM oscillation device 43 outputs a control signal for controlling the gate voltage to be applied to the second element 20. Specifically, the PWM oscillation device 43 generates and outputs the control signals so as to control the On/Off states of the switch SW1 and the switch SW2 on the basis of a PWM reference signal input thereto from an external ECU or the like. The details of the control signals generated on the basis of a PWM reference output will be described later.

The mode determination unit 50 determines the operation mode of each of the first element 10 and the second element 20. The operation mode mentioned herein allows a distinction to be made between whether a current flows mainly in the IGBT part or in the diode part in the insulated-gate bipolar transistor. In the following description, a state where a current flows mainly in the IGBT part is referred to as a forward conduction mode and a state where a current flows mainly in the diode part is referred to as a reverse conduction mode.

The mode determination unit 50 in the present embodiment determines the operation mode of each of the first element 10 and the second element 20 on the basis of the direction of the current flowing in the load 200. The inverter 100 includes a load current detection unit 60 connected in series to the load 200. The load current detection unit 60 is a current meter which detects a load current I flowing in the load 200 inclusive of the direction thereof. The load current detection unit 60 outputs the load current I to the mode determination unit 50 on the assumption that the load current I when flowing from the connection point between the first element 10 and the second element 20 toward the load 200 is a positive current and the load current I when flowing in the reverse direction is a negative current.

The mode determination unit 50 determines the operation mode on the basis of whether the load current I output from the load current detection unit 60 is positive or negative. Specifically, when the load current I is positive, the state is established in which the current flows mainly in the IGBT part 11 in the first element 10 (upper arm) and in the diode part 22 in the second element 20 (lower arm). Accordingly, the mode determination unit 50 determines that the operation mode of the first element 10 is the forward conduction mode and determines that the operation mode of the second element 20 is the reverse conduction mode. On the other hand, when the load current I is negative, the state is established in which the current flows mainly in the diode part 12 in the first element 10 and in the IGBT part 21 in the second element 20. Accordingly, the mode determination unit 50 determines that the operation mode of the first element 10 is the reverse conduction mode and the operation mode of the second element 20 is the forward conduction mode.

Next, referring to FIG. 2, a description will be given of a detailed structure of the first element 10 and the second element 20. Note that, since the first element 10 and the second element 20 are the reverse conducting insulated-gate bipolar transistors equivalent to each other, the description will be given without making a distinction therebetween. In FIG. 2, the same components as shown in FIG. 1 are associated with the reference numerals given to the components of the first element 10. Also, in FIG. 2, each of the p-conductivity-type impurity layers of a semiconductor substrate 70 is hatched, while the hatching of the n-conductivity-type impurity layers thereof is omitted.

As shown in FIG. 2, the reverse conducting insulated-gate bipolar transistor as the reverse conducting switching element in the present embodiment is formed in the semiconductor substrate 70 having a first main surface 70a and a second main surface 70b as the back surface thereof. The IGBT part 11 functioning as the switching element and the diode part 12 functioning as a diode are formed in the same semiconductor substrate 70.

On the first main surface 70a, a cathode electrode 71 made of, e.g., aluminum is formed. The cathode electrode 71 corresponds to a cathode terminal in the diode part 12 or to a collector terminal in the IGBT part 11. The cathode electrode 71 also corresponds to a first electrode.

As also shown in FIG. 2, in the surface layer of the semiconductor substrate 70 which is closer to the first main surface 70a, an n-conductivity-type cathode region 72a is formed so as to come in contact with the cathode electrode 71. In addition, in the same layer as that of the cathode region 72a, a p-conductivity-type collector region 72b is formed. The collector region 72b is adjacent to the cathode region 72a, while being in contact with the cathode electrode 71. The interface between the cathode region 72a and the collector region 72b serves as the boundary between the diode part 12 and the IGBT part 11. The cathode region 72a corresponds to a first impurity region.

On the cathode region 72a, an n-conductivity-type first buffer region 73a is stacked while, on the collector region 72b, an n-conductivity-type second buffer region 73b is stacked. For the sake of convenience, the first buffer region 73a and the second buffer region 73b have the different names, but these regions 73a and 73b are continued regions made of substantially the same impurity layer.

On the first buffer region 73a, an n-conductivity-type first drift region 74a is stacked while, on the second buffer region 73b, an n-conductivity-type second drift region 74b is stacked. For the sake of convenience, the first drift region 74a and the second drift region 74b have the different names, but these regions 74a and 74b are continued regions made of substantially the same impurity layer. Note that the impurity concentration in each of the drift regions 74a and 74b is set lower than that in each of the buffer regions 73a and 73b.

On the first drift region 74a, a p-conductivity-type first field extension prevention region 75a is stacked while, on the second drift region 74b, a p-conductivity-type second field extension prevention region 75b is stacked. For the sake of convenience, the first field extension prevention region 75a and the second field extension prevention region 75b have the different names, but these field extension prevention regions 75a and 75b are continued regions made of substantially the same impurity layer.

On the first field extension prevention region 75a, an n-conductivity-type first barrier region 76a is stacked while, on the second field extension prevention region 75b, an n-conductivity-type second barrier region 76b is stacked. For the sake of convenience, the first barrier region 76a and the second barrier region 76b have the different names, but these barrier regions 76a and 76b are continued regions made of substantially the same impurity layer.

In the diode part 12, the first field extension prevention region 75a and the first barrier region 76a each described above are formed to inhibit holes from being injected from an anode region 77a described later into the first drift region 74a and limit a reverse current when the voltage applied to the diode part 12 is changed from a forward bias to a reverse bias. This can reduce a reverse recovery current compared to that in a diode in which the first field extension prevention region 75a and the first barrier region 76a are not formed and thus improve a recovery characteristic. However, since a pn junction formed by the first field extension prevention region 75a and the first barrier region 76a interrupts the flow of a forward current in the diode part 12, the forward voltage VF is increased.

On the first barrier region 76a, the p-conductivity-type anode region 77a is stacked while, on the second barrier region 76b, a p-conductivity-type body region 77b is stacked. For the sake of convenience, the anode region 77a and the body region 77b have the different names, but these regions 77a and 77b are continued regions made of substantially the same impurity layer. Note that the anode region 77a corresponds to a second impurity region.

In the surface layer of the semiconductor substrate 70 adjacent to the second main surface 70b, n-conductivity-type emitter regions 78 are formed so as to be surrounded by the body region 77b. On the second main surface 70b, an anode electrode 79 is formed so as to come in contact with the emitter regions 78, the body region 77b, and the anode region 77a. The anode electrode 79 corresponds to an anode terminal in the diode part 12 or to an emitter terminal in the IGBT part 11. The emitter regions 78 correspond to a third impurity region, while the anode electrode 79 corresponds to a second electrode.

As shown in FIG. 2, the IGBT part 11 has, as impurity layers, the collector region 72b, the second buffer region 73b, the second drift region 74b, the second field extension prevention region 75b, the second barrier region 76b, the body region 77b, and the emitter regions 78. On the other hand, the diode part 12 has, as impurity layers, the cathode region 72a, the first buffer region 73a, the first drift region 74a, the first field extension prevention region 75a, the first barrier region 76a, and the anode region 77a.

The individual impurity layers located as substantially the same layer do not prevent the corresponding regions from having different impurity concentrations in accordance with respective electric properties required of the IGBT part 11 and the diode part 12. The respective impurity concentrations in these regions should appropriately be set.

The reverse conducting insulated-gate bipolar transistors further have trench gates 80 formed to extend from the second main surface 70b in the thickness direction of the semiconductor substrate 70 and reach the drift regions 74a and 74b. In the IGBT part 11, the trench gates 80 extend through the body region 77b, the second barrier region 76b, and the second field extension prevention region 75b to reach the second drift region 74b. In the diode part 12, the trench gates 80 extend through the anode region 77a, the first barrier region 76a, and the first field extension prevention region 75a to reach the first drift region 74a.

Each of the trench gates 80 includes an insulating film 81 deposited on the inner surface of the trench formed to extend from the second main surface 70b in the thickness direction of the semiconductor substrate 70 and reach the drift region 74a or 74b and a conductive gate electrode 82 formed so as to fill the trench. The gate electrode 82 and the emitter electrode 79 are insulated from each other by the insulating film 81 interposed therebetween. The emitter regions 78 formed in the IGBT part 11 are formed so as to come into contact with the trench gates 80. When a voltage higher than that applied to the anode electrode 79 is applied to the gate electrodes 82, a channel is formed in the body region 77b and the second field extension prevention region 75b to allow an output current resulting from an IGBT operation to flow between the anode electrode 79 and the cathode electrode 71.

The p-conductivity-type anode region 77a, the p-conductivity-type body region 77b, the n-conductivity-type first and second barrier regions 76a and 76b, and the p-conductivity-type first and second field extension prevention regions 75a and 75b form pnp-type parasitic transistors. For holes, the n-conductivity-type barrier regions 76a and 76b serve as a potential barrier against the p-conductivity-type regions. However, the barrier height thereof can be controlled using the voltage applied to the gate electrodes 82.

As described above, particularly to the gate electrode 82, a voltage lower than a voltage at the anode electrode 79 (which is the emitter electrode of the IGBT) by V2 can be applied. In other words, the potential at the gate electrode 82 can be set negative relative to the potential at the anode electrode 79. This allows the barrier height to vary so as to eliminate the potential barrier of the barrier regions 76a and 76b.

In the present embodiment, the electromotive force V2 from the voltage source 42 is set to a value which allows a channel to be formed at least in the first barrier region 76a. In other words, the voltage V2 is set so as to be a threshold voltage Vth or more of the parasitic transistor formed of the anode region 77a, the first barrier region 76a, and the first field extension prevention region 75a in the diode part 12. The voltage V2 corresponds to a parasitic gate voltage.

In the present embodiment, the n-conductivity-type corresponds to a first conductivity type, while the p-conductivity-type corresponds to a second conductivity type. The relationship between the conductivity types may also be inverted. In this case, the relationship between the anode and the cathode is also inverted.

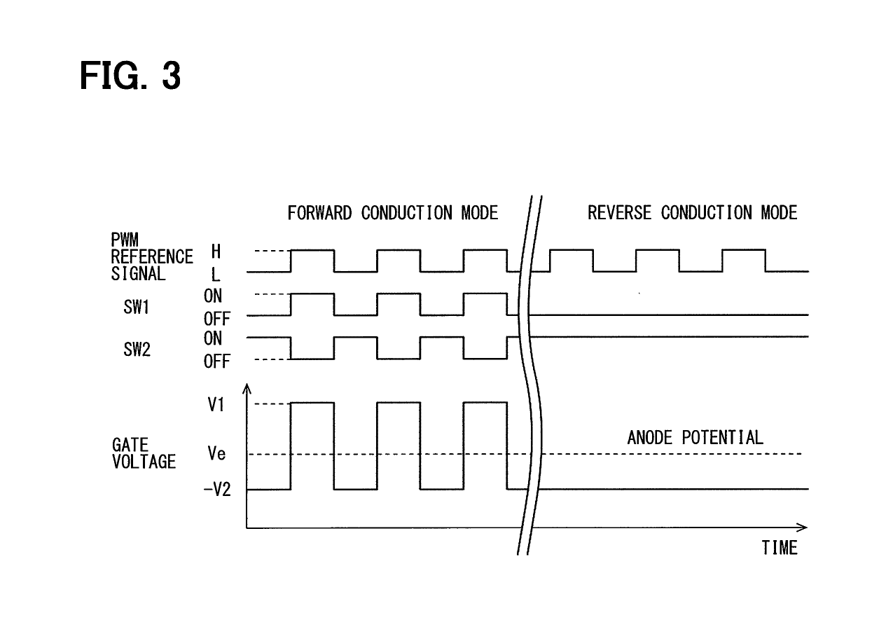

Next, referring to FIG. 3, a description will be given of the operation of the semiconductor device in the present embodiment, particularly of those of the first element 10 and the second element 20.

The first element 10 is driven by the first drive unit 30. The first drive unit 30 supplies a gate voltage corresponding to the operation mode of the first element 10 determined by the mode determination unit 50 to the gate electrodes 82 of the first element 10. On the other hand, the second element 20 is driven by the second drive unit 40. The second drive unit 40 supplies a gate voltage corresponding to the operation mode of the second element 20 determined by the mode determination unit 50 to the gate electrodes 82 of the second element 20.

The first drive unit 30 and the second drive unit 40 are formed of circuits equivalent to each other, but the operations thereof are independent of each other. FIG. 3 shows a timing chart for the operations of the switch SW1 and the switch SW2, but does not show that the first drive unit 30 and the second drive unit 40 operate in synchronization. That is, the first drive unit 30 and the second drive unit 40 independently operate in accordance with the respective operation modes of the first element 10 and the second element 20. The following description will be given using the second drive unit 40 as an example, the detailed configuration of which is shown in FIG. 2.

The PWM oscillation device 43 generates control signals to be output to the switch SW1 and the switch SW2 on the basis of the PWM reference signal input thereto from the external ECU and information related to the operation modes input thereto from the mode determination unit 50.

When the load current I flowing in the load 200 is negative by way of example, the second element 20 is in the forward conduction mode. In this case, the PWM oscillation device 43 outputs a control signal synchronous with the PWM reference signal to the switch SW1. In the present embodiment, as shown in FIG. 3, the switch SW1 is turned on when the PWM reference signal is High. On the other hand, to the switch SW2, the PWM oscillation device 43 outputs a control signal in a phase opposite to that of the control signal to the switch SW1. As shown in FIG. 2, when the switch SW1 is on (closed) and the switch SW2 is off (open), a voltage Ve+V1 is output as the gate voltage. When the switch SW1 is off and the switch SW2 is on, a voltage Ve−V2 is output as the gate voltage. Note that Ve denotes the voltage at the anode electrode 79 which satisfies Ve=GND in the second element 20 disposed on the Low side. On the other hand, Ve in the first element 10 disposed on the High side corresponds to a voltage at the cathode electrode 71 in the second element 20.

Conversely, when the load current I flowing in the load 200 is positive by way of example, the second element 20 is in the reverse conduction mode. In this case, the PWM oscillation device 43 outputs a control signal to the switch SW1 such that the switch SW1 stays in the off state irrespective of the PWM reference signal. On the other hand, the PWM oscillation device 43 outputs a control signal to the switch SW2 such that the switch SW2 stays in the on state irrespective of the PWM reference signal. That is, in the reverse conduction mode, the state is established in which the voltage −V2 is constantly applied to the gate electrodes 82, while the channel is formed in the first barrier region 76a.

Note that the first drive unit 30 also drives the first element 10 in accordance with the timing chart shown in FIG. 3, similarly to the second drive unit 40. However, when the load current I flowing in the load 200 is negative, the first element 10 is in the reverse conduction mode while, when the load current is positive, the first element 10 is in the forward conduction mode.

Next, a description will be given of the advantageous effects achieved by using the semiconductor device in the present embodiment.

In the state where the reverse conducting insulated-gate bipolar transistor is conductive as an IGBT as a result of the application of a voltage V1 to the gate electrode 82 in synchronization with the PWM reference signal, i.e., in the forward conduction mode, when the PWM reference signal is High, a gate voltage which turns on the IGBT is applied and, when the PWM reference signal is Low, a gate voltage which turns off the IGBT is applied. This allows the IGBT to correctly perform a switching operation in synchronization with the PWM reference signal.

On the other hand, in the reverse conduction mode, the negative voltage −V2 that is equal to or greater than the threshold voltage Vth of the parasitic transistor is applied to the gate electrodes 82. Consequently, the channel is formed in the first barrier region 76a to serve as a movement path for holes. Since the first barrier region 76a is present with the conductivity type thereof inverted to the p-conductivity-type, the first field extension prevention region 75a, the first barrier region 76a, and the anode region 77a function as an integrated p-conductivity-type pseudo-anode region. As a result, holes can be injected from the anode region 77a into the first drift region 74a without being inhibited. This can reduce the forward voltage VF even in the diode part 12 having the first barrier region 76a and the first field extension prevention region 75a. Therefore, it is possible to reduce the forward voltage VF during energization of the diode during which it is particularly required to reduce a loss by reducing the forward voltage VF, while ensuring the superiority of the recovery characteristic achieved by having the first barrier region 76a and the first field extension prevention region 75a. That is, it is possible to simultaneously improve the recovery characteristic and reduce the forward voltage VF.

### First Modification

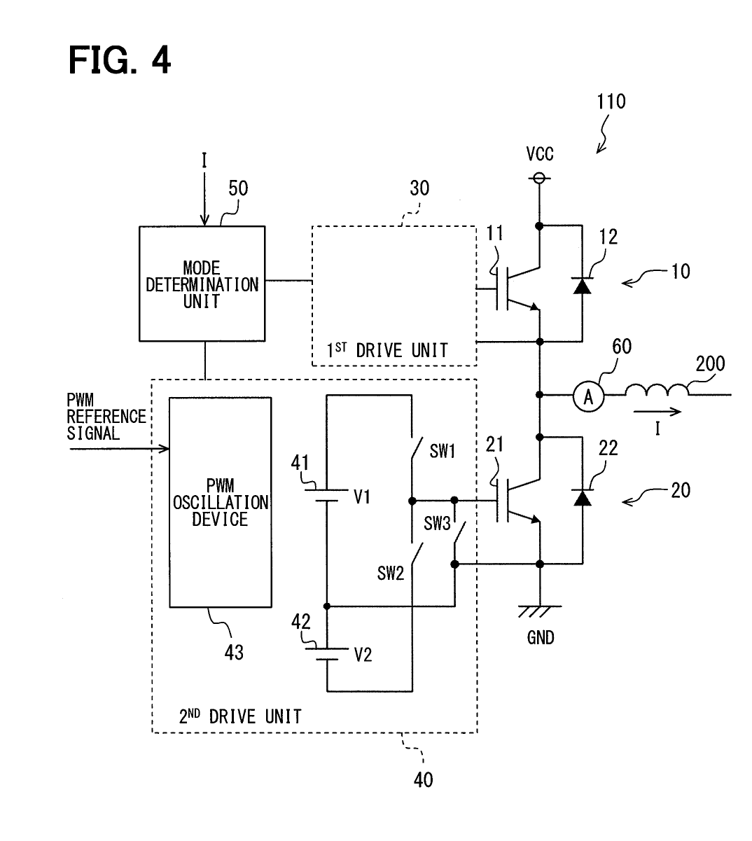

An inverter 110 in the present modification has a configuration obtained by adding a switch SW3 to each of the first drive unit 30 and the second drive unit 40 in the first embodiment described above. As shown in FIG. 4, the switch SW3 is the switch for setting the gate electrodes and the anode electrodes (serving also as the emitter electrodes) of the IGBT parts 11 and 21 at the same potential. Note that the PWM oscillation device 43 receives the PWM reference signal output from the external ECU and input thereto and generates control signals to be output to the switches SW1, SW2, and SW3, but the illustration thereof is omitted in FIG. 4.

The drive units 30 and 40 in the first embodiment are configured such that, in the forward conduction mode in which currents flow mainly in the IGBT parts 11 and 21, the voltage −V2 is applied to the gate electrodes 82 during the period except while the voltage V1 is applied to the gate electrodes 82. However, in the forward conduction mode in which the diode parts 21 and 22 are not energized, the voltage −V2 need not necessarily be applied to the gate electrodes 82. The present modification adopts a configuration which inhibits unnecessary application of the negative voltage −V2.

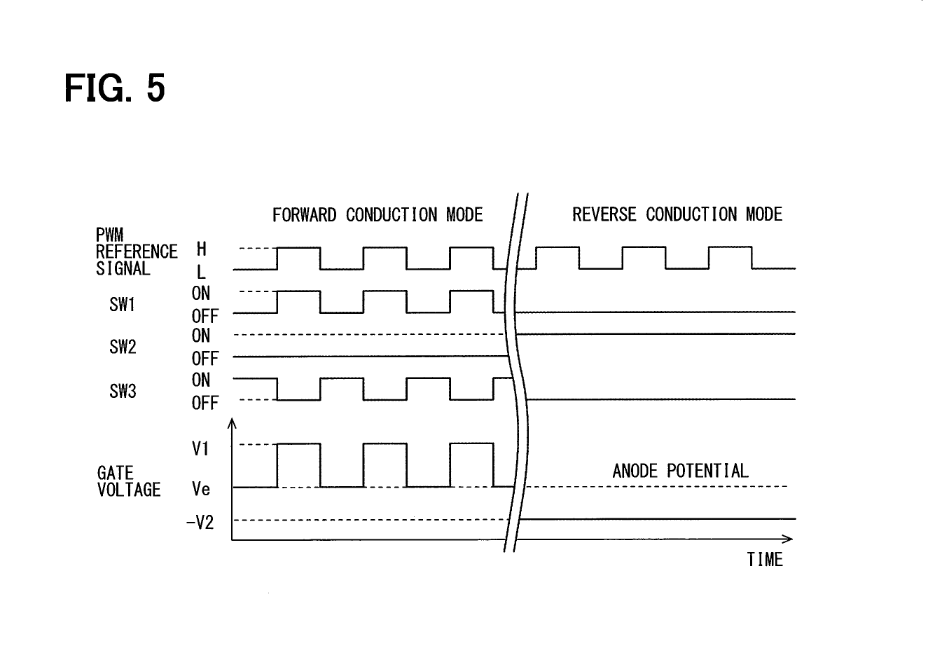

Referring to FIG. 5, a description will be given of a specific operation. In the same manner as in the first embodiment, the respective configurations of the first drive unit 30 and the second drive unit 40 are equivalent to each other, and therefore the description will be given of the second drive unit 40 by way of example.

When the load current I flowing in the load 200 is negative by way of example, the second element 20 is in the forward conduction mode. In this case, the PWM oscillation device 43 outputs the control signal synchronous with the PWM reference signal to the switch SW1. In the same manner as in the first embodiment, in the present modification also, as shown in FIG. 5, the switch SW1 is turned on when the PWM reference signal is High. On the other hand, to the switch SW3, the PWM oscillation device 43 outputs the control signal in the phase opposite to that of the control signal to the switch SW1. As shown in FIG. 4, when the switch SW1 is on (closed) and the switch SW3 is off (open), the voltage Ve+V1 is output as the gate voltage. When the switch SW1 is off and the switch SW3 is on, the voltage Ve, i.e., a potential at the anode electrode 79 is output as the gate voltage. In the present modification, in the forward conduction mode, the switch SW2 is constantly in the off state to prevent the parasitic gate voltage as the negative voltage from being applied to the gate electrodes 82.

Conversely, when the load current I flowing in the load 200 is positive by way of example, the second element 20 is in the reverse conduction mode. In this case, the PWM oscillation device 43 outputs control signals to the switch SW1 and the switch SW3 such that the switches SW1 and SW3 stay in the off state irrespective of the PWM reference signal. On the other hand, the PWM oscillation device 43 outputs a control signal to the switch SW2 such that the switch SW2 stays in the on state irrespective of the PWM reference signal. That is, in the reverse conduction mode, the state is established in which the voltage −V2 is constantly applied to the gate electrodes 82, while the channel is formed in the first barrier region 76a.

In the inverter 110 in the present modification, the application of the parasitic gate voltage in the forward conduction mode is not performed on the inverter 100 according to the first embodiment. This can reduce the number of times the voltage −V2 is applied compared to that in the inverter 100 in the first embodiment. Consequently, it is possible to control the performance of the voltage source 42 for generating the voltage V2. Note that the circuit scale of each of the drive parts 30 and 40 of the inverter 100 in the first embodiment can be reduced compared to that in the inverter 110 in the present modification. When there is a request to prioritize a circuit scale reduction over the control of the performance of the power voltage source 42, it is preferable to adopt the inverter 100 in the first embodiment.

### Second Modification

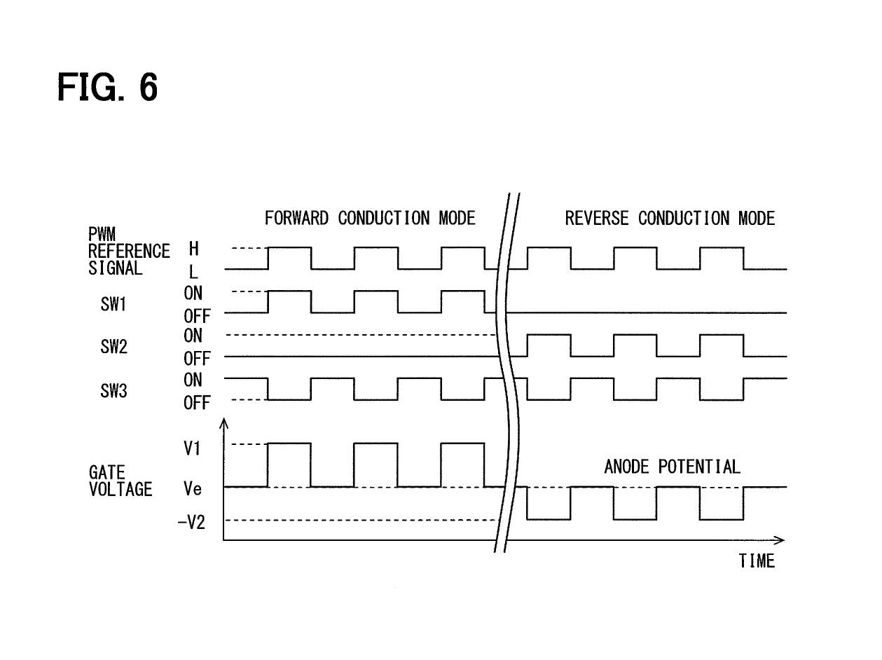

In the first embodiment and the first modification, the description has been given of the form in which, when the operation mode of the reverse conducting switching element is the reverse conduction mode, the parasitic gate voltage is constantly applied to the gate electrode 82. By contrast, in the present modification, as shown in FIG. 6, even during the reverse conduction mode, the gate voltage varies in synchronization with the PWM reference signal. Note that the circuit configuration of each of the first drive unit 30 and the second drive unit 40 is the same as in the first modification, and therefore a description thereof is omitted. Also, the operation in the forward conduction mode is the same as in the first modification, and therefore a description thereof is omitted.

In the present modification, the PWM oscillation device 43 outputs a control signal to the switch SW1 such that the switch SW1 stays in the off state regardless of the PWM reference signal. On the other hand, the PWM oscillation device 43 outputs control signals synchronous with the PWM reference signal to the switches SW2 and SW3. As shown in FIG. 6, when the PWM reference signal is High, the switch SW2 is turned on. Also, to the switch SW3, the PWM oscillation device 43 outputs a control signal in a phase opposite to that of the control signal to the switch SW2. The control signal causes the gate voltage to be repeatedly turned on and off between the two values of the anode potential Ve and the voltage −V2. Specifically, when the PWM reference signal is High, the gate voltage is the Low-level parasitic gate voltage (−V2) and, when the PWM reference signal is Low, the gate voltage is the High-level anode potential (Ve).

In most inverters, the first element 10 forming the upper arm and the second element 20 forming the lower arm are neither simultaneously turned on nor simultaneously turned off except during a dead time. In general, the PWM reference signal for the upper arm and the PWM reference signal for the lower arm are mutually inverted. Accordingly, in the reverse conduction mode, currents flow mainly in the diode parts 12 and 22 when the PWM reference signal is High.

In the inverter in the present modification, the parasitic gate voltage is applied to the gate electrodes 82 on condition that the PWM reference signal is High. This can reduce the forward voltage VF under conditions that currents flow in the diode parts 12 and 22 and achieve a lower loss. Also, a recovery occurs at the moment when the pair of arms shifts to the on state but, at that time, the gate electrode 82 is at the anode potential. This allows a hole injection inhibiting effect to achieve a lower recovery loss.

### Third Modification

Each of the first embodiment and the first and second modifications has shown the example in which the operation modes of the first element 10 and the second element 20 are determined on the basis of the direction of the load current I. The determination of the operation modes can be made on the basis of the directions of the output currents of the first element 10 and the second element 20 or the output voltages thereof, other than the direction of the load current I.

An output current is a collector current in a reverse conducting insulated-gate bipolar transistor and is a drain region in a reverse conducting MOSFET. Note that the output current is equal to a cathode current.

An output voltage is a collector-to-emitter voltage in the reverse conducting insulated-gate bipolar transistor and is a drain-to-source voltage in the reverse conducting MOSFET. Note that the output voltage is equal to a cathode-to-anode voltage.

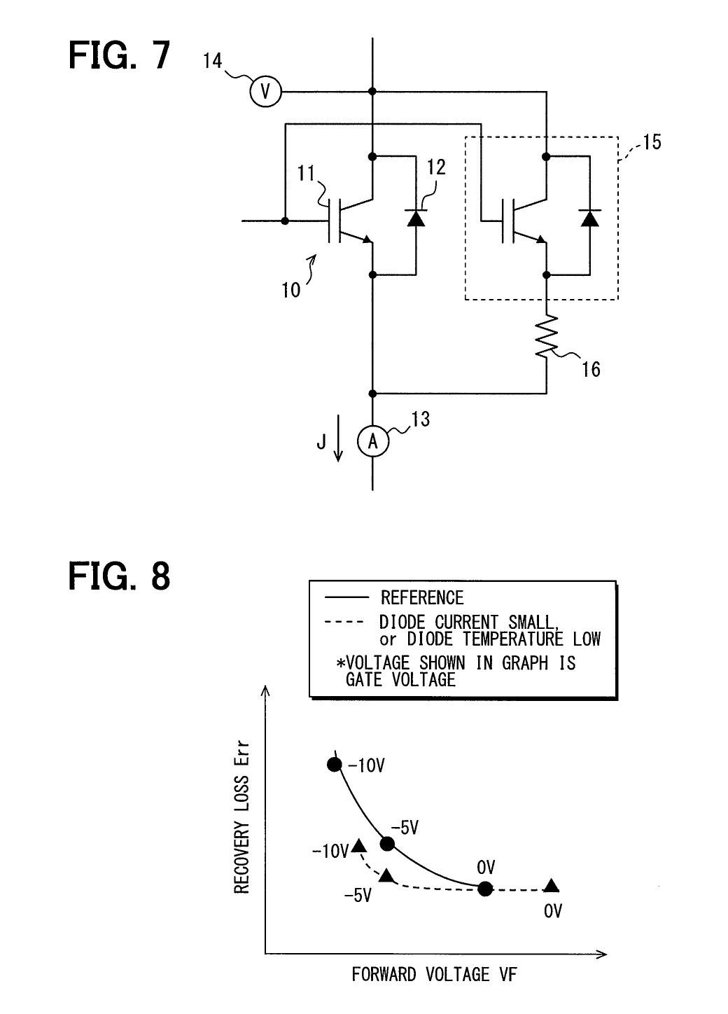

In the present modification, as shown in FIG. 7, a description will be given of a semiconductor device including an output current detection unit 13 which detects respective output currents J of the first element 10 and the second element 20 and a voltage detection unit 14 which detects a voltage between the cathode electrode 71 and the anode electrode 79. Note that, since the first element 10 and the second element 20 are equivalent to each other, FIG. 7 representatively shows the first element 10 and a detection system provided around the first element 10.

As shown in FIG. 7, the semiconductor device in the present modification has, in parallel with the first element 10, a series circuit including a sense cell 15 and a shunt resistor 16. The cell pitch of the sense cell 15 is adjusted such that the collector current proportional to the output current of the first element 10 flows. The detection of the direction of the collector current in the sense cell 15 is synonymous to the detection of the direction of the output current J of the first element 10. The collector current in the sense cell 15 can be obtained by being calculated from the voltage across the shunt resistor 16 and the resistance of the shunt resistor 16. Alternatively, as shown in FIG. 7, the semiconductor device may also include the output current detection unit 13 connected in series to the first element 10 to detect the output current of the first element 10. In this case, the output current detection unit 13 linearly detects the direction of the current in the first element 10.

As also shown in FIG. 7, the semiconductor device may also include the voltage detection unit 14 which detects a voltage between the anode electrode 79 and the cathode electrode 71 and consequently detects a potential at the cathode electrode 71. In this case, it is possible to detect the value of the current flowing in the first element 10 on the basis of the amount of an anode-to-cathode voltage drop.

The mode determination unit 50 in the present modification is communicatively connected to the output current detection unit 13, the voltage detection unit 14, and the voltage detection unit detecting the voltage across the shunt resistor 16 not illustrated to determine the operation mode of the first element 10 or the second element 20 on the basis of whether the output current is positive or negative (i.e., the direction thereof) and the cathode-to-anode voltage.

In the configuration described above, the output current detection unit 13 detects the output current on the assumption that the direction of the current flowing from the cathode electrode 71 to the anode electrode 79 in the first element 10 is positive. In this case, when the output current is positive, the operation mode of the first element 10 is the forward conduction mode. Conversely, when the output current is negative, the operation mode of the first element 10 is the reverse conduction mode. Note that, since the driving of the semiconductor device in each of the operation modes is the same as in the first embodiment, a detailed description thereof is omitted.

When the voltage of the cathode electrode 71 is higher than the voltage at the anode electrode 79, the voltage detection unit 14 detects the cathode voltage as a positive voltage. In this case, when the cathode voltage is positive, the operation mode of the first element 10 is the forward conduction mode. Conversely, when the cathode voltage is negative, the operation mode of the first element 10 is the reverse conduction mode. Note that, since the driving of the semiconductor device in each of the operation modes is the same as in the first embodiment, a detailed description thereof is omitted.

As described above, the determination of the operation mode can also be made on the basis of the directions of the output currents of the first element 10 and the second element 20 or the output voltages thereof, other than the direction of the load current I.

Note that, by way of example, FIG. 7 shows the form including each of the sense cell 15, the output current detection unit 13, and the voltage detection unit 14. However, as long as the form includes any one of the sense cell 15, the output current detection unit 13, and the voltage detection unit 14, the operation mode of the first element 10 can be determined.

### Fourth Modification

Each of the first embodiment and the first, second, and third modifications has described above the example in which the application of the parasitic gate voltage to the gate electrodes 82 is determined on the basis of only the operation mode of the reverse conducting switching element. However, in addition to the operation mode, various conditions may also be used as bases for the determination.

As shown in FIG. 8, it is proved that, under conditions in which a current flowing in a diode is smaller or the element temperature of the diode is lower than in the Forward Voltage VF-Recovery Loss Err characteristic (solid line) of the diode obtained under given conditions, the forward voltage VF tends to increase. In other words, under conditions in which the current flowing in the diode is small or the element temperature of the diode is low, when the parasitic gate voltage is applied to the gate electrodes 82, a more noticeable effect of further reducing the forward voltage VF and consequently reducing the loss can be achieved.

The currents flowing in the diode parts 12 and 22 are equal to the output currents of the reverse conducting switching elements. Using the output current detection unit 13 shown in FIG. 7, the currents flowing in the diode parts 12 and 22 can be detected. That is, the output current detection unit 13 shown in FIG. 7 is an output current detection unit and is also a diode current detection unit. Note that the output currents of the reverse conducting switching elements can also be detected via the shunt resistor 16 or the voltage detection unit 14 shown in FIG. 7 or via the load current detection unit 60 shown in FIG. 4. In such a case, at least any one of the shunt resistor 16, the voltage detection unit 14, and the load current detection unit 60 corresponds to the output current detection unit.

For example, the inverter 110 which performs an operation as performed in the first modification or the second modification (FIG. 5 or 6) is assumed. At this time, when the diode current detected by the output current detection unit 13 is larger than a predetermined threshold in the reverse conduction mode, the first and second drive units 30 and 40 cause the switch SW2 to stay in the Off state and cause the switch SW3 to stay in the On state, while causing the operation described in each of the modifications to be performed on condition that the diode current is the predetermined threshold or less. As a result, only when the condition that the diode currents flowing in the diode parts 12 and 22 are the predetermined threshold or less is satisfied, an inverter capable of applying the parasitic gate voltage to the gate electrodes 82 can be formed.

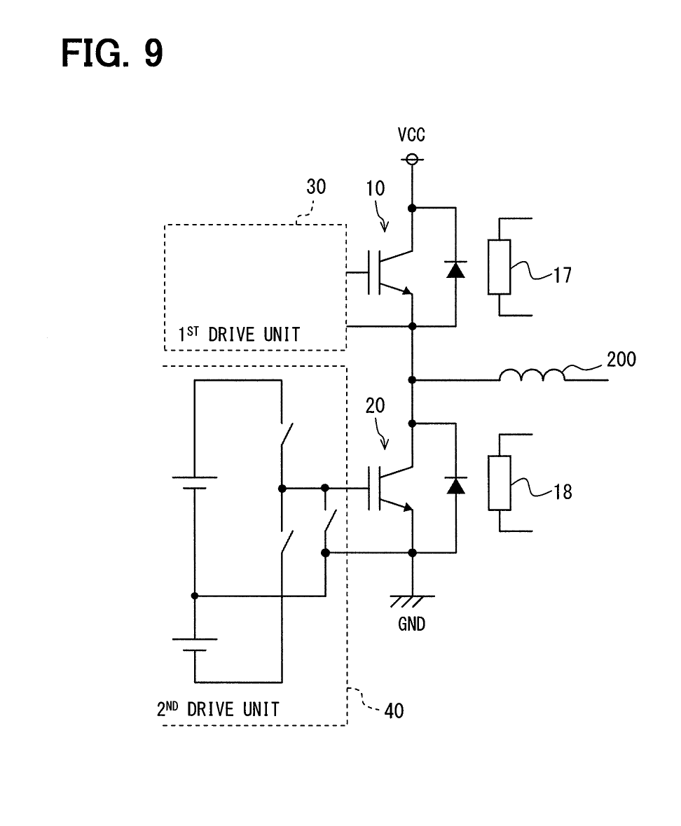

Alternatively, as shown in FIG. 9, the inverter 110 may also have a first temperature detection unit 17 for detecting the temperature of the first element 10 in the vicinity of the first element 10 and have a second temperature detection unit 18 for detecting the temperature of the second element 20 in the vicinity of the second element 20. The first temperature detection unit 17 and the second temperature detection unit 18 correspond to a temperature detection unit.

For example, the inverter 110 which performs an operation as performed in the first modification or the second modification (FIG. 5 or 6) is assumed. At this time, when the respective element temperatures of the first element 10 and the second element 20 detected by the first temperature detection unit 17 and the second temperature detection unit 18 are higher than a predetermined threshold in the reverse conduction mode, the first and second drive units 30 and 40 cause the switch SW2 to stay in the Off state and cause the switch SW3 to stay in the On state, while causing the operation described in each of the modifications to be performed on condition that the element temperatures are the predetermined threshold or less. As a result, only when the condition that the element temperatures in the diode parts 12 and 22 are the predetermined threshold or less is satisfied, an inverter capable of applying the parasitic gate voltage to the gate electrodes 82 can be formed.

In general, as the power source voltage VCC is lower, a recovery loss in a diode tends to be smaller. On the other hand, when a reverse conducting switching element is used for a typical motor driver or boosting converter, there is the need to supply an intended output power even when the power source voltage VCC drops and it is required to handle a larger current. Accordingly, an energy loss resulting from the forward voltage VF tends to increase.

In view of the foregoing, in a voltage region where the power source voltage VCC is relatively small, a reduction in the forward voltage VF is required while, in a voltage region where the power source voltage VCC is relatively large, an improved recovery characteristic is required.

Note that, in the example shown in FIG. 1, the power source voltage VCC is equal to the cathode voltage in the first element 10 when the first element 10 is Off, while the power source voltage VCC is equal to the cathode voltage in the second element 20 when the second element 20 is Off. Accordingly, the power source voltage VCC is equal to the cathode voltage in the third modification. The cathode voltage can be detected by the voltage detection unit 14 shown in FIG. 7. That is, the voltage detection unit 14 is a voltage detection unit and directly detects the power source voltage VCC or detects the voltage at the cathode electrode 79.

For example, the inverter 110 which performs an operation as performed in the first modification or the second modification (FIG. 5 or 6) is assumed. At this time, when the power source voltage VCC or the cathode voltage detected by the voltage detection unit 14 is larger than a predetermined threshold in the reverse conduction mode, the first and second drive units 30 and 40 cause the switch SW2 to stay in the Off state and cause the switch SW3 to stay in the On state, while causing the operation described in each of the modifications to be performed on condition that the power source voltage VCC or the cathode voltage during an Off period is the predetermined threshold or less. As a result, only when the condition that the power source voltage VCC or the cathode voltage applied to the diode parts 12 and 22 is the predetermined threshold or less is satisfied, an inverter capable of applying the parasitic gate voltage to the gate electrodes 82 can be formed.

### Second Embodiment

In the present embodiment, a description will be given of a form in which a diode and a semiconductor device including the diode are applied to a boosting circuit, specifically a boosting converter. Note that, in each of the drawings used to describe the present embodiment, the same electronic elements as the components of the inverter described in the first embodiment are given the same reference numerals.

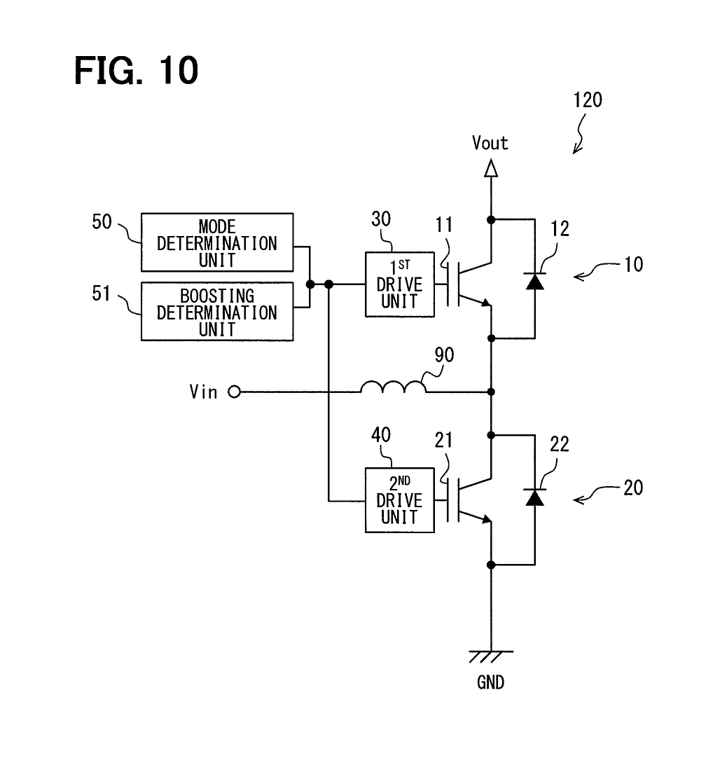

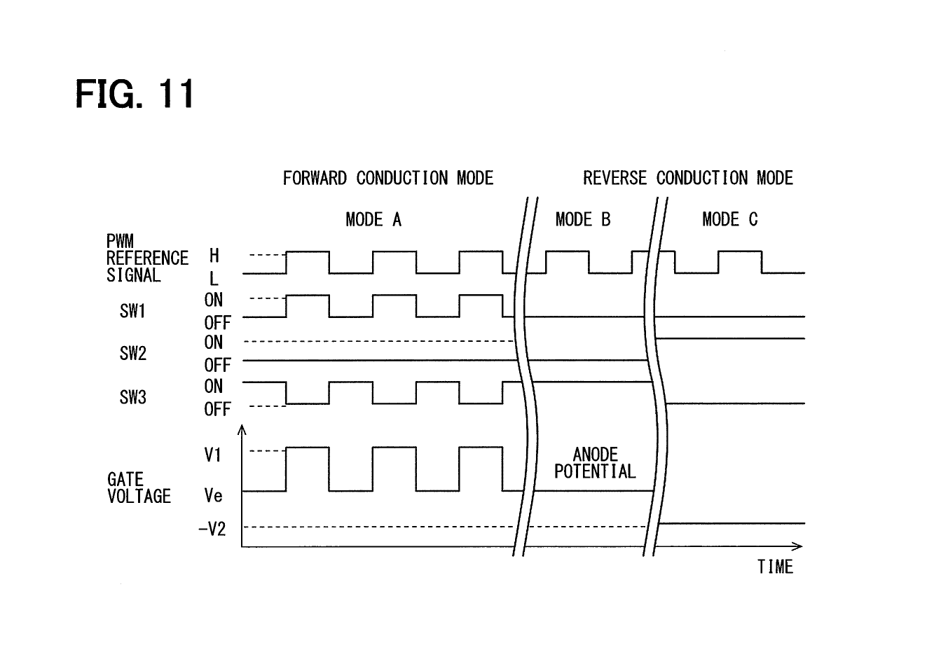

First, referring to FIGS. 10 and 11, a description will be given of a schematic configuration of the boosting converter according to the present embodiment.

As shown in FIG. 10, a boosting converter 120 includes the first element 10, the second element 20, and a reactor 90 and has a circuit configuration according to the circuit configuration of a typical boosting regulator. In addition, the boosting converter 120 includes a boosting determination unit 51 which determines whether or not the boosting converter 120 is performing a boosting operation. Note that, similarly to the inverter 110 described in the first modification or the second modification, the boosting converter 120 includes the drive units 30 and 40 capable of applying the voltage V1, the anode potential Ve, and the negative voltage −V2 to the gate electrodes 82 of the first element 10 and the second element 20 and the mode determination unit 50 which determines the respective driven states of the elements 10 and 20.

As shown in FIG. 10, the boosting converter 120 has a configuration in which, between an output terminal Vout and the ground GND, the first element 10 and the second element 20 are connected in series. Also, to the connection point between the first element 10 and the second element 20, one of the ends of the reactor 90 is connected, while the other end of the reactor 90 serves as an input terminal Vin.

To the gate electrode 82 of the first element 10, the first drive unit 30 is connected. In the same manner as in the first embodiment and the first to fourth modifications, the drive unit 30 applies a gate voltage to the gate electrode 82 of the first element 10 on the basis of the PWM reference signal. To the gate electrode 82 of the second element 20, the second drive unit 40 is connected. The second drive unit 40 applies a gate voltage to the gate electrode 82 of the second element 20 on the basis of the PWM reference signal.

In the same manner as in the first embodiment and the first to fourth modifications, the mode determination unit 50 determines the operation modes of the first element 10 and the second element 20. As a determination method, the same method as used in each of the first embodiment and the first to fourth modifications can be used.

When the load connected to the output terminal Vout is a motor, the mode determination can also be made on the basis of the operation of the motor, i.e., the motor driven by the present power source circuit. The drive mode can also be determined on the basis of, e.g., whether a powered operation of supplying power from the Vin side to the Vout side or a regenerative operation of collecting power from the Vout side to the Vin side is performed. Specifically, in the first element 10 forming the upper arm, a current flows mainly in the diode part 12 during the powered operation so that, during the powered operation, the drive mode is the reverse conduction mode. Conversely, during the regenerative operation, the drive mode is the forward conduction mode. On the other hand, in the second element 20 forming the lower arm, a current flows mainly in the IGBT part 21 during the powered operation so that, during the powered operation, the drive mode is the forward conduction mode. Conversely, during the regenerative operation, the drive mode is the reverse conduction mode.

In the forward conduction mode, the first drive unit 30 and the second drive unit 40 in the present embodiment perform driving in the same manner as in the first embodiment. In the present embodiment, this mode is referred to as a mode A. On the other hand, in the reverse conduction mode, the first drive unit 30 and the second drive unit 40 have two more operation modes. As shown in FIG. 11, during the reverse conduction mode, the first drive unit 30 and the second drive unit 40 have a mode B in which the same voltage (anode potential) as that at the anode electrode 79 is applied as the gate voltage and a mode C in which the parasitic gate voltage as a voltage lower than that at the anode electrode 79 is applied as the gate voltage. The operation in the mode C is the same as the operation in the reverse conduction mode in the first modification. Conditions for the first and second drive units 30 and 40 to perform driving in each of the modes will be described later in detail.

The boosting determination unit 51 determines whether or not the boosting converter 120 is performing the boosting operation. The boosting determination unit 51 determines that the boosting converter 120 is performing the boosting operation when, e.g., a voltage at the output terminal Vout is higher than a predetermined threshold that is higher than a voltage at the input terminal Vin and determines that the boosting converter 120 is not performing the boosting operation (performing a non-boosting operation) when the voltage at the output terminal Vout is the threshold or less.

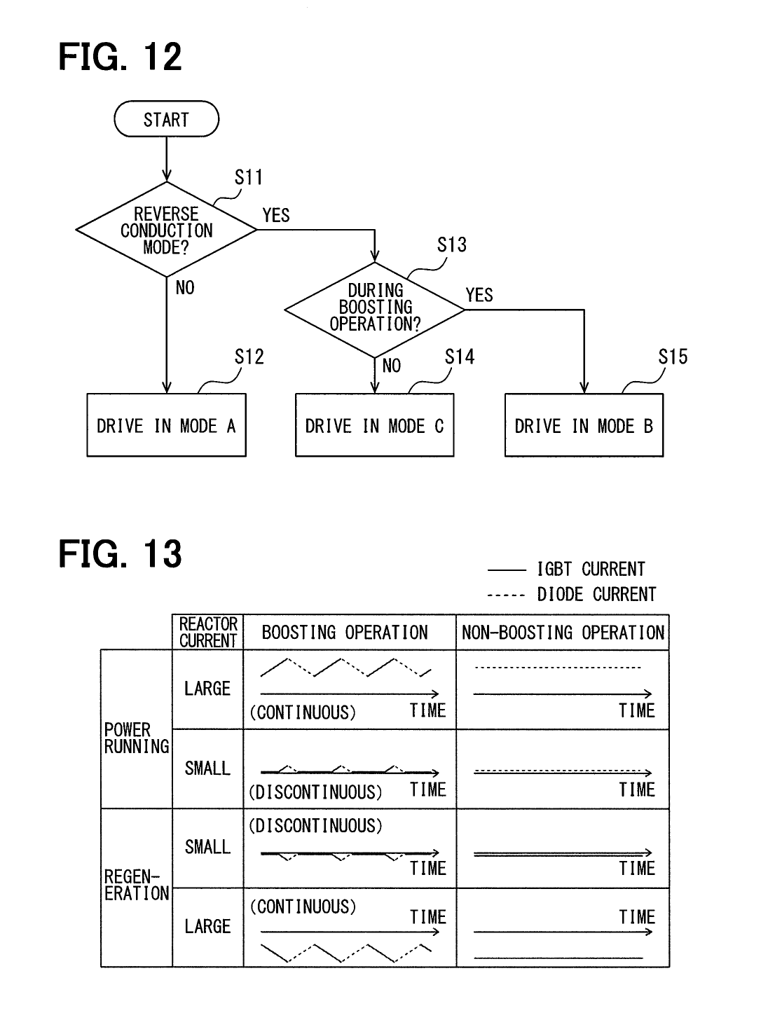

Next, referring to FIG. 12, a description will be given of the operation of the boosting converter 120 in the present embodiment.

First, as shown in FIG. 12, Step S11 is performed. Step S11 is the step in which the mode determination unit 50 determines whether the operation mode of each of the first element 10 and the second element 20 is the forward conduction mode or the reverse conduction mode. In the reverse conducting insulated-gate bipolar transistor, the operation mode is the forward conduction mode when current flows mainly in the IGBT part 11, 21, while the operation mode is the reverse conduction mode when current flows mainly in the diode part 12, 22. Also, as described above, during the powered operation, the first element 10 is in the reverse conduction mode, while the second element 20 is in the forward conduction mode. On the other hand, during the regenerative operation, the first element 10 is in the forward conduction mode, while the second element 20 is in the reverse conduction mode.

In Step S11, when the element 10, 20 is in the reverse conduction mode, NO is given as a result of the determination and Step S12 is performed. In other words, when the element 10, 20 is in the forward conduction mode, Step S12 is performed. Step S12 is the step in which the drive unit 30, 40 outputs the gate voltage in the mode A shown in FIG. 11. In the forward conduction mode, when the PWM reference signal is High, a gate voltage which turns on the IGBT is applied while, when the PWM reference signal is Low, a gate voltage which turns off the IGBT is applied. Consequently, the IGBT can correctly perform the switching operation in synchronization with the PWM.

On the other hand, in Step S11, when the element 10, 20 is in the reverse conduction mode, YES is given as a result of the determination and Step S13 is performed. Step S13 is the step in which the boosting determination unit 51 determines whether the boosting converter 120 is performing the boosting operation or the non-boosting operation. As described above, the boosting determination unit 51 in the present embodiment determines whether or not the boosting operation is performed on the basis of the voltage at the output terminal Vout.

In Step S13, when the voltage at the output terminal Vout is the predetermined threshold or less, the boosting converter 120 is performing the non-boosting operation so that NO is given as a result of the determination. In this case, Step S14 is performed. Step S14 is the step in which the drive unit 30, 40 outputs the gate voltage in the mode C shown in FIG. 12. The wording “is performing the non-boosting operation” means that, e.g., in FIG. 10, the gate voltages applied to the first element 10 and the second element 20 are not PWM-controlled, the first element 10 is in a normally on state with the voltage V1 being applied to the gate electrode 82 thereof, and the second element 20 is in a normally off state with generally the same voltage as that at the anode electrode 79 being applied thereto. In this case, the diode part 12, 22 does not perform a recovery operation so that the forward voltage VF is required to be lower. By supplying the gate voltage in the mode C shown in FIG. 11, the parasitic gate voltage is applied to the gate electrode 82. That is, the diode part 12, 22 can be operated in the state where the forward voltage VF is reduced.

On the other hand, in Step S13, when the voltage at the output terminal Vout is higher than the predetermined threshold, it is determined that the boosting converter 120 is performing the boosting operation so that YES is given as a result of the determination. In this case, Step S15 is performed. Step S15 is the step in which the drive unit 30, 40 outputs the gate voltage in the mode B shown in FIG. 12. The state where YES is given as a result of the determination in Step S13 is established by the first element 10 when, e.g., the PWM-controlled gate voltage is applied to the second element 20 and the second element 20 is in the forward conduction mode and contributing to boosting. In this state, the first element 10 is in the reverse conduction mode, while the boosting converter 120 is performing the boosting operation, so the recovery operation occurs in the diode part 12. Accordingly, it is appropriate to perform driving in the mode B in which improving the recovery characteristic is prioritized over reducing the forward voltage VF by applying the parasitic gate voltage to the gate electrode 82.

Next, a description will be given of the advantageous effects achieved by adopting the semiconductor device and the boosting converter 120 in the present embodiment.

By adopting the boosting converter 120, with regard to the boosting operation, to the switching element in the forward conduction mode in which the current flows mainly in the IGBT part 11, 21, the PWM-controlled gate voltage having the voltage V1 as the High-level voltage and the anode potential Ve as the Low-level voltage is applied. Consequently, the boosting of the input voltage Vin can reliably be performed.

On the other hand, to the switching element in the reverse conduction mode in which the current flow mainly in the diode part 21, 22, a voltage can be applied in the mode B in which the parasitic gate voltage is not applied to the gate electrode 82 during the boosting operation during which a recovery may occur. During the non-boosting operation in which it is required to reduce the forward voltage VF, a voltage can be applied in the mode C in which the parasitic gate voltage is applied to the gate electrode 82.

By thus adopting the boosting converter 120, it is possible to simultaneously improve the recovery characteristic and reduce the forward voltage VF.

### Fifth Modification

The second embodiment has shown the example in which the boosting determination unit 51 determines that the boosting operation is performed when the voltage at the output terminal Vout is higher than the predetermined threshold and that the non-boosting operation is performed when the voltage at the output terminal Vout is the threshold or less. However, for the determination of the boosting state made by the boosting determination unit 51, a means other than the comparison between the voltage at the output terminal Vout and the threshold can also be used.

For example, a configuration may also be adopted in which the external ECU which outputs the PWM reference signal to be input to the first drive unit 30 and the second drive unit 40 is connected to the boosting determination unit 51, and the PWM reference signal can also be input to the boosting determination unit 51.

In this configuration, when the PWM-controlled PWM reference signal is input to the boosting determination unit 51, the boosting determination unit 51 determines that the boosting converter 120 is performing the boosting operation. When the PWM reference signal is not input to the boosting determination unit 51, the boosting determination unit 51 determines that the boosting converter 120 is performing the non-boosting operation. The state where the PWM reference signal is not input to the boosting determination unit 51 includes herein not only the state where the PWM reference signal is not input at all, but also the state where the PWM reference signal is not input at predetermined periods, such as where a normally High signal or a normally Low signal is input.

A description of which one of the application patterns in the mode A, the mode B, and the mode C is used by the drive unit 30, 40 to output the gate voltage is omitted since the drive units 30 and 40 output the gate voltages in accordance with the flow chart shown in FIG. 12, in the same manner as in the second embodiment. A configuration in which the boosting determination unit 51 receives a signal showing whether the boosting operation or the non-boosting operation is performed from the external ECU may also be adopted.

### Sixth Modification

Each of the second embodiment and the fifth modification has described the example in which the application pattern for the gate voltage output from the drive unit 30, 40 is determined on the basis of whether the boosting converter 120 is performing the boosting operation or the non-boosting operation. However, the application pattern can also be determined on the basis of the current mode of the current flowing in the reactor 90.

FIG. 13 is a view showing the behavior of a load current when the boosting converter 120 is used as the power source circuit which supplies power to a load. Note that the direction in which the current flows from the positive/negative input terminal Vin to the connection point between the first element 10 and the second element 20 is assumed to be positive, while the reverse direction is assumed to be negative.

When a reactor current is large, the reactor current does not cross zero so that a current mode is a continuous operation. On the other hand, when the reactor current is small, the load current includes the zero point so that the current mode is a discontinuous operation. In this system, switching between the continuous operation and the discontinuous operation and switching between power running and regeneration are determined by the external ECU and implemented by the PWM reference signal output from the external ECU. During the continuous operation, a recovery occurs so that it is not preferable to apply the parasitic gate voltage to the gate electrode 82. Conversely, during the discontinuous operation, no recovery occurs and power consumption can be reduced by reducing the forward voltage VF. Therefore, it is preferable to apply the parasitic gate voltage to the gate electrode 82.

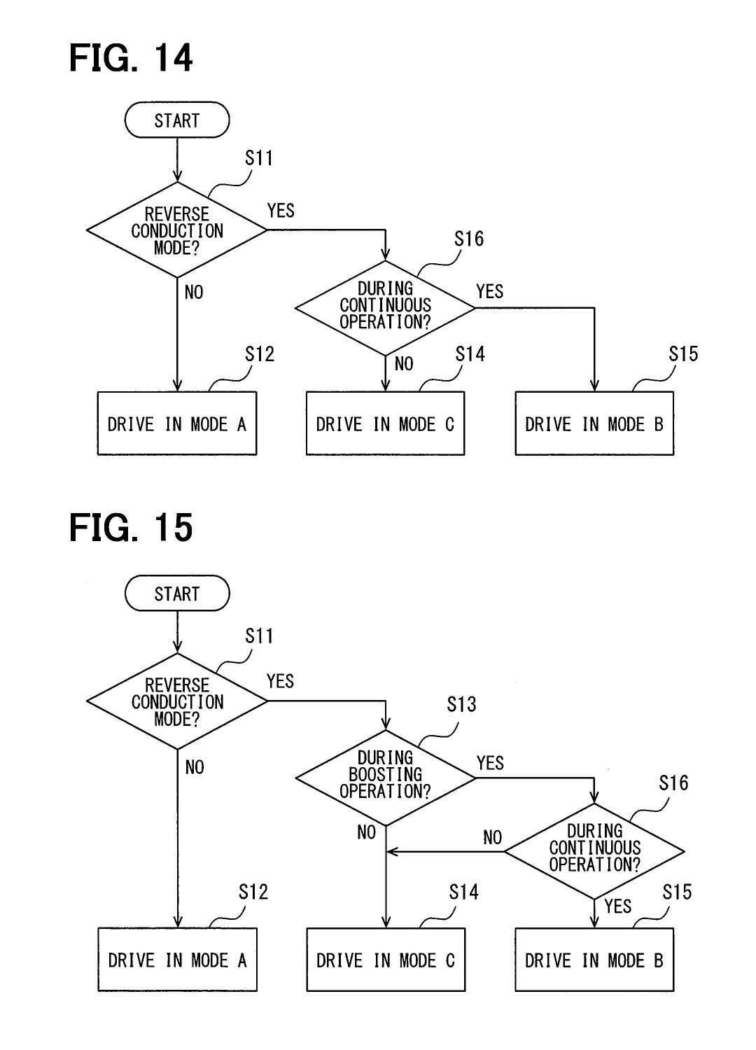

Thus, as shown in FIG. 14, the application pattern can also be determined on the basis of the current mode of the current flowing in the reactor. This can be implemented by replacing Step S13 in which whether or not the boosting operation is performed is determined in the operation flow for the boosting converter 120 in the second embodiment that has been described with reference to FIG. 12 with Step S16 in which whether or not the reactor current is performing the continuous operation is determined, as shown in FIG. 14.

A description will be given step by step. As shown in FIG. 14, Step S11 is performed first. Step S11 is the same as Step S11 in the second embodiment. When NO is given as a result of the determination in Step S11, the operation mode is the forward conduction mode so that the current flows mainly in the IGBT part 11, 21. Accordingly, for, e.g., a boosting operation, the gate voltage synchronous with the PWM reference signal is applied, i.e., the gate voltage is applied in the mode A shown in Step S12.

When YES is given as a result of the determination in Step S11, the process advances to Step S16. Step S16 is the step in which, e.g., the external ECU which monitors the reactor current determines whether or not the reactor current is performing the continuous operation or the discontinuous operation. As described above, during the continuous operation, a recovery occurs so that it is not preferable to apply the parasitic gate voltage to the gate electrodes 82. Accordingly, when YES is given as a result of the determination in Step S16, the gate voltage is applied in the mode B shown in Step S15.

Conversely, during the discontinuous operation, no recovery occurs and power consumption can be reduced by reducing the forward voltage VF, and therefore it is preferable to apply the parasitic gate voltage to the gate electrodes 82. Accordingly, when NO is given as a result of the determination in Step S16, the gate voltage is applied in the mode C shown in Step S15 so that the parasitic gate voltage is applied to the gate electrode 82. As a result, it is possible to suppress power consumption.

Note that, in determining whether the reactor current is performing the continuous operation or the discontinuous operation, it is also possible to determine that the reactor current is performing the continuous operation on the basis of the fact that the absolute value of the minimal value of the reactor current which periodically oscillates under PWM control is a predetermined threshold or more, other than the means which detects whether or not the reactor current includes the zero point. In that case, Step S16 shown in FIG. 14 is replaced with the step of determining whether or not the absolute value of the minimal value of the reactor current is the predetermined threshold or more. When NO is given as a result of the determination, the operation performed by the reactor current is the discontinuous operation so that the process advances to Step S14. When YES is given as a result of the determination, the operation performed by the reactor current is the continuous operation so that the process advances to Step S15. It may also be possible for the ECU which determines the switching between the continuous operation and the discontinuous operation to make the determination in Step S15.

To provide a basis on which the application patterns for the gate voltages output from the drive units 30 and 40 are determined, it is possible to combine the boosting converter described in the second embodiment with the boosting converter described in the sixth modification. During the non-boosting operation, no recovery occurs so that the operation of reducing the forward voltage VF is preferable.

While the boosting operation is performed and the continuous operation is performed, in the same manner as in the sixth modification, a recovery occurs so that it is not preferable to apply the parasitic gate voltage to the gate electrodes 82. Conversely, while the boosting operation is performed and the discontinuous operation is performed, no recovery occurs and power consumption can be reduced by reducing the forward voltage VF. Therefore, it is preferable to apply the parasitic gate voltage to the gate electrodes 82.

To implement the operation described above, as shown in FIG. 15, when YES is given as a result of the determination in Step S13 in the operation flow in the second embodiment, Step S16 described in the sixth modification is performed appropriately. In accordance with the operation flow, while the boosting converter 120 is performing the boosting operation and the reactor current is performing the continuous operation under the assumption that the first element 10 and the second element 20 are operating in the reverse conduction mode, a recovery occurs. Accordingly, the recovery characteristic is prioritized so that the parasitic gate voltage is not applied. On the other hand, under conditions other than those described above, no recovery occurs. Accordingly, a reduction in the forward voltage VF is prioritized so that the parasitic gate voltage is applied to the gate electrodes 82.

By thus adopting the boosting converter 120, it is possible to simultaneously improve the recovery characteristic and reduce the forward voltage VF.

### Third Embodiment

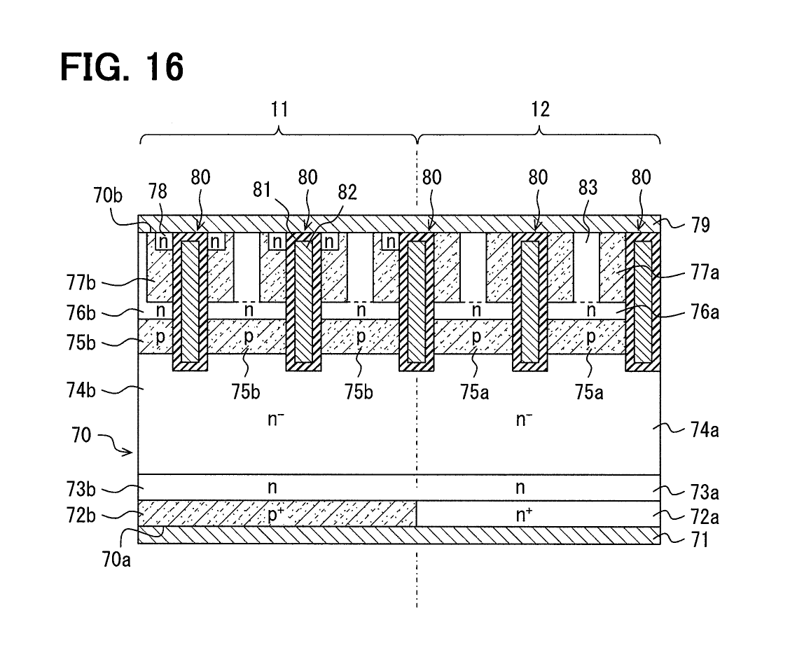

The first and second embodiments and the first to sixth modifications have described that the reverse conducting insulated-gate bipolar transistors, which are the first element 10 and the second element 20, have the structure shown in FIG. 2. As shown in FIG. 16, the reverse conducting insulated-gate bipolar transistors preferably have n-conductivity-type pillar regions 83 in addition to the structure described with reference to FIG. 2. Each of the pillar regions 83 is formed to extend from the second main surface 70b of the semiconductor substrate 70 in the thickness direction through the anode region 77a or the body region 77b and reach the first barrier region 76a or the second barrier region 76b. The pillar regions 83 are diffusion layers doped with the same impurity as doping the first and second barrier regions 76a and 76b to have generally the same concentrations as those of the first and second barrier regions 76a and 76b. The pillar region 83 and the barrier regions 76a and 76b are at generally the same potentials.

Due to the pillar regions 83 provided in each of the reverse conducting insulated-gate bipolar transistors, the anode electrode 79 is short-circuited to the pillar regions 83 via a metal-semiconductor junction surface. Since the pillar regions 83 and the first barrier region 76a are at substantially the same potentials, the potential difference between the first barrier region 76a and the anode electrode 79 is substantially equal to a voltage drop at the metal-semiconductor junction surface. The voltage drop at the metal-semiconductor junction surface is smaller than a built-in voltage at the pn junction between the anode region 77a and the first barrier region 76a. This inhibits the injection of holes from the anode region 77a into the first drift region 74a.

When the voltage between the anode electrode 79 and the cathode electrode 71 is switched from a forward bias to a reverse bias, a reverse current is limited by the pn junctions between the field extension prevention regions 75a and 75b and the drift regions 74a and 74b. In the diode part 12, the injection of holes from the anode region 77a into the first drift region 74a is inhibited during the application of the forward bias. Accordingly, a reverse recovery current is small and a reverse recovery time is short. The diode part 12 allows a reduction in switching loss without the need to perform life-time control on the first drift region 74a.

Note that, by setting the impurity concentration in each of the pillar regions 83 higher than the impurity concentration in the first barrier region 76a, it is possible to reduce the potential difference between the first barrier region 76a and the anode electrode 79 during the application of the forward bias without reducing the thickness of the anode region 77a. The diode part 12 described above inhibits the occurrence of a reach-through due to the reverse bias and allows a reduction in switching loss without reducing a breakdown voltage.

The present embodiment has shown the example in which the pillar regions 83 are formed also in the IGBT part 11. However, as long as the pillar regions 83 are formed at least in the diode part 12, it is possible to achieve a hole injection inhibiting effect. Accordingly, the pillar regions 83 need not necessarily be formed in the IGBT part 11.

### Other Embodiments

Each of the second embodiment and the fifth and sixth modifications has shown, as an example of the circuit configuration of the boosting converter 120, the configuration in which the two reverse conducting insulated-gate bipolar transistors are connected in series. However, the upper arm may also be formed only of the diode. In the case of adopting this configuration, the detailed structure of the diode is the structure shown in FIG. 2 or 16 in which only the diode part 12 is formed in the semiconductor substrate 70, and the parasitic gate voltage can be applied to the gate electrodes 82. By applying the parasitic gate voltage to the gate electrodes 82 in the reverse conduction mode in which the forward bias is applied to the diode part 12, it is possible to reduce the forward voltage VF.

In each of the embodiments and the modifications described above, the description has been given using the reverse conducting insulated-gate bipolar transistor as an example of the reverse conducting switching element. However, as the reverse conducting switching element, a reverse conducting MOSFET may also be used. In the case of using the MOSFET, the collector region 72b of the switching element region (which is the IGBT part 11 in each of the embodiments described above) shown in FIG. 2 or FIG. 16 serves as the n-conductivity-type drain region, which serves as each of the switching element and the diode element. That is, the switching element region and the diode part 12 need not be formed separately. Note that the emitter region 78 shown in FIG. 2 or FIG. 16 serves as the source region. In such a form, the region substantially functioning as the switching element and the region functioning as the diode are formed in parallel.

Also, the first embodiment has shown the example in which the gate voltage applied to the gate electrodes 82 has the two values of the voltage V1 and the voltage −V2, while the first modification has shown the example in which the gate voltage applied to the gate electrodes 82 has the three values of the voltage V1, the anode potential Ve, and the voltage −V2. However, these are only exemplary, and the gate voltage applied to the gate electrodes 82 may also shift among four or more values. For example, the second modification has shown the example in which the gate voltage applied to the gate electrodes 82 shifts between Ve and V2 in the reverse conduction mode, but it may also be possible to adopt a configuration in which the gate voltage applied to the gate electrodes 82 shifts between a voltage lower than Ve and the voltage V2.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

1. A diode, comprising:
a first electrode disposed on a first main surface of a semiconductor substrate;
a first-conductivity-type first impurity region disposed in a surface layer of the semiconductor substrate adjacent to the first main surface and stacked on the first electrode;
a first-conductivity-type drift region stacked on the first impurity region and having an impurity concentration lower than the impurity concentration of the first impurity region;
a second-conductivity-type second impurity region stacked on the drift region; and
a second electrode disposed on the second impurity region and on a second main surface of the semiconductor substrate which is opposite to the first main surface,
the diode further comprising:
a first-conductivity-type barrier region disposed between the drift region and the second impurity region and having an impurity concentration higher than the impurity concentration of the drift region;
a second-conductivity-type field extension prevention region disposed between the barrier region and the drift region; and
a trench gate disposed to extend from the second main surface through the second impurity region and the barrier region and to reach the field extension prevention region, the trench gate having a gate electrode for applying a gate voltage, wherein
the gate electrode is configured to be applied with a parasitic gate voltage as the gate voltage, the parasitic gate voltage having an absolute value of a potential difference with the second electrode that is equal to or greater than a threshold voltage of a parasitic transistor formed of the second impurity region, the barrier region, and the field extension prevention region.

2. The diode according to claim 1, further comprising:
a first-conductivity-type pillar region disposed to extend through the second impurity region so as to connect the second electrode and the barrier region.

3. A semiconductor device, comprising:
a reverse conducting switching element in which a diode and a switching element are disposed in parallel in a same semiconductor substrate;
a drive unit which applies a gate voltage to the reverse conducting switching element; and
a mode determination unit which determines whether the reverse conducting switching element is driven in a forward conduction mode in which a current flows mainly in the switching element or in a reverse conduction mode in which a current flows mainly in the diode,
wherein the diode includes:
a first electrode disposed on a first main surface of the semiconductor substrate;
a first-conductivity-type first impurity region disposed in a surface layer of the semiconductor substrate adjacent to the first main surface and stacked on the first electrode;
a first-conductivity-type first drift region stacked on the first impurity region and having an impurity concentration lower than the impurity concentration of the first impurity region;
a second-conductivity-type second impurity region stacked on the first drift region;
a second electrode disposed on the second impurity region and on a second main surface of the semiconductor substrate which is opposite to the first main surface;
a first-conductivity-type first barrier region disposed between the first drift region and the second impurity region and having an impurity concentration higher than the impurity concentration of the first drift region; and
a second-conductivity-type first field extension prevention region disposed between the first barrier region and the first drift region,
wherein the switching element includes:
a first-conductivity-type second drift region;
a second-conductivity-type body region disposed in the surface layer of the semiconductor substrate adjacent to the second main surface; and
a first-conductivity-type third impurity region disposed in the surface layer of the semiconductor substrate adjacent to the second main surface to be surrounded by the body region,
wherein the diode and the switching element include:
a trench gate disposed to extend from the second main surface through the second impurity region and the first barrier region and to reach the first drift region, the trench gate having a gate electrode for applying the gate voltage, and
wherein, in the reverse conduction mode, the drive unit is configured to apply a parasitic gate voltage as the gate voltage, the parasitic gate voltage having an absolute value of a potential difference with the second electrode that is equal to or greater than a threshold voltage of a parasitic transistor formed of the second impurity region, the first barrier region, and the first field extension prevention region.

4. The semiconductor device according to claim 3, further comprising:
a first-conductivity-type pillar region disposed to extend through the second impurity region so as to connect the second electrode and the first barrier region.

5. The semiconductor device according to claim 3,
wherein, in the reverse conduction mode, the drive unit applies the gate voltage that is a PWM controlled gate voltage having at least two values of a high level and a low level, and
wherein the value at the low level corresponds to the parasitic gate voltage.

6. The semiconductor device according to claim 3, further comprising:
a diode current detection unit configured to detect a current value of a diode current flowing between the second electrode and the first electrode during the reverse conductive mode,
wherein the drive unit applies the parasitic gate voltage as the gate voltage on condition that the diode current detected by the diode current detection unit is a predetermined threshold or less.

7. The semiconductor device according to claim 3, further comprising:
a temperature detection unit configured to detect a temperature of the reverse conducting switching element,
wherein the drive unit applies the parasitic gate voltage as the gate voltage on condition that the temperature of the reverse conducting switching element detected by the temperature detection unit is a predetermined threshold or less.

8. The semiconductor device according to claim 3,
wherein the drive unit applies the parasitic gate voltage as the gate voltage on condition that a power source voltage supplied to the reverse conducting switching element is a predetermined threshold or less.

9. The semiconductor device according to claim 8, further comprising:
a voltage detection unit configured to detect a voltage applied between the second electrode and the first electrode so as to detect the power source voltage,
wherein the drive unit applies the parasitic gate voltage as the gate voltage on condition that the voltage detected by the voltage detection unit is a predetermined threshold or less.

10. The semiconductor device according to claim 3,
wherein the reverse conducting switching element is one of two reverse conducting switching element connected in series to respectively form an upper arm and a lower arm,
wherein, to a connection point between the upper arm and the lower arm, one end of a reactor is connected,
wherein, to the other end of the reactor which is opposite to the one end connected to the reverse conducting switching elements, an input voltage is applied, and
wherein a boosting circuit is configured to boost the input voltage on the basis of the gate voltage which is pulse-controlled by the drive unit.

11. The semiconductor device according to claim 10, further comprising:
a boosting determination unit configured to determine whether or not the boosting circuit is performing a boosting operation,
wherein the drive unit applies the parasitic gate voltage as the gate voltage on condition that the boosting circuit is not performing the boosting operation.

12. The semiconductor device according to claim 11,
wherein the boosting determination unit determines that the boosting circuit is performing the boosting operation on the basis of a fact that an output voltage of the boosting circuit is higher than a predetermined threshold.

13. The semiconductor device according to claim 11,
wherein the boosting determination unit determines that the boosting circuit is performing the boosting operation on the basis of a fact that a PWM reference signal serving as a reference for generating the PWM-controlled gate voltage is input to the drive unit.

14. The semiconductor device according to claim 3,
wherein the drive unit applies the parasitic gate voltage as the gate voltage on condition that a reactor current flowing in the reactor is performing a discontinuous operation including a zero point.

15. The semiconductor device according to claim 3,
wherein the reverse conducting switching element is one of two reverse conducting switching elements connected in series to respectively provide an upper arm and a lower arm and, to a connection point between the upper arm and the lower arm, one end of a load is connected,
the semiconductor device further comprising:
a load current detection unit configured to detect a load current flowing in the load,
wherein the load current flowing from the connection point toward the load is defined as positive,
wherein the mode determination unit determines that, when the load current is positive, the reverse conducting switching element providing the upper arm is in the forward conduction mode and the reverse conducting switching element providing the lower arm is in the reverse conduction mode and that, when the load current is negative, the reverse conducting switching element providing the upper arm is in the reverse conduction mode and the reverse conducting switching element providing the lower arm is in the forward conduction mode.

16. The semiconductor device according to claim 3, further comprising:
an output current detection unit configured to detect a current value of an output current of the reverse conducting switching element,
wherein, the output current flowing from the first electrode to the second electrode is defined as positive,
wherein the mode determination unit determines that, when the output current is positive, the reverse conducting switching element is in the forward conduction mode and that, when the output current is negative, the reverse conducting switching element is in the reverse conduction mode.

17. The semiconductor device according to claim 3, further comprising:
a voltage detection unit configured to detect a voltage at the first electrode in the reverse conducting switching element,
wherein the mode determination unit determines that, when the voltage at the first electrode is higher than a voltage at the second electrode, the reverse conducting switching element is in the forward conduction mode and that, when the voltage at the first electrode is lower than the voltage at the second electrode, the reverse conducting switching element is in the reverse conduction mode.
